(19) United States
(12) Patent Application Publication
(10) Pub. No.: US 2009/0061642 A1
(43) Pub. Date: Mar. 5, 2009

(54) NOZZLE ASSEMBLY, APPARATUS FOR SUPPLYING PROCESSING SOLUTIONS HAVING THE SAME AND METHOD OF SUPPLYING PROCESSING SOLUTIONS USING THE SAME

(76) Inventor: Chong-Eui Ha, Seoul (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 12/199,857

(22) Filed: Aug. 28, 2008

(30) Foreign Application Priority Data
Aug. 30, 2007 (KR) 10-2007-0087367

(51) Int. Cl. H01L 21/306; H01L 21/31

(52) U.S. Cl. 438/745; 118/320; 134/153; 156/345.23; 438/758; 257/E21.219; 257/E21.24

(57) ABSTRACT

In a nozzle assembly for supplying processing solutions, the nozzle assembly includes a housing, a plurality of supply units arranged in the housing and through which different processing solutions flow onto the substrate, and a plurality of nozzles connected to the supply units, respectively, in such a configuration that a first nozzle selected from the nozzles is directed to the substrate and the remaining nozzles excluding the first nozzle are directed away from the substrate. Accordingly, the mechanical structure of the nozzle assembly may be simplified and the nozzles directed away from the substrate may be prevented from being contaminated by the processing solutions that are injected onto the substrate through the nozzle directed to the substrate.

### PRIORITY STATEMENT

This application claims priority under 35 U.S.C. §119 to Korean Patent Application No. 2007-87367, filed on Aug. 30, 2007 in the Korean Intellectual Property Office (KIPO), the contents of which are herein incorporated by reference in their entirety.

### BACKGROUND OF THE INVENTION

1. Field of the Invention

Example embodiments of the present invention relate to a nozzle assembly for supplying processing solutions, an apparatus for supplying processing solutions having the nozzle assembly, and a method of supplying processing solutions using the apparatus. More particularly, example embodiments of a nozzle assembly for supplying processing solutions onto a semiconductor device such as a wafer, an apparatus for supplying processing solutions having the nozzle assembly, and a method of supplying processing solutions onto the substrate using the apparatus.

2. Description of the Related Art

In general, semiconductor memory devices and flat panel display devices, such as a liquid crystal display (LCD) device, a plasma display device and an organic light-emitting diode (OLED) display device, are manufactured through various repeated unit processes on a substrate such as a semiconductor substrate (silicon wafer) or a glass substrate.

For example, various unit processes such as a thin film process, a patterning process for the thin film, and a cleaning process are performed on a semiconductor substrate or glass substrate, to thereby form circuit patterns having various electric and optical characteristics on the substrate. Each of the unit processes is usually performed in various process facilities under some recipes peculiar thereto in a clean room.

Particularly, when a thin layer is formed on a semiconductor substrate by a spin coating process or a cleaning and a drying process is performed on the semiconductor substrate, processing solutions are supplied onto the substrate while the substrate is rotated on a rotating chuck. For example, various cleaning solutions are supplied onto the substrate in a cleaning process for removing impurities from a semiconductor substrate such as a wafer.

The processing solutions are usually supplied onto a central portion of the rotating substrate through a plurality of nozzles. The nozzles are selectively transferred over the central portion of the substrate by a transfer unit and the rotation speed of the semiconductor substrate and flow rates of the processing solutions are controlled in accordance with preset recipes of each process.

FIG. 1 is a view illustrating a schematic structure of a conventional apparatus for supplying processing solutions onto a substrate.

Referring to FIG. 1, the conventional apparatus 10 for supplying the processing solutions is widely used for processing semiconductor substrates 1 such as silicon wafers and includes a plurality of nozzle pipes 11a, 11b and 11c, a driving unit 12 and a solution reservoir 15.

A general facility for processing the substrate 1 includes a rotating chuck 2 to which the substrate is secured, a bowl 3 enclosing the chuck on which the substrate 1 is positioned.

A first end portion of each of the nozzle pipes 11a, 11b and 11c is connected to a nozzle through which the processing solutions are supplied onto the substrate 1. The first end portion of the nozzle pipe is bent downward to the substrate 1, so that the first end portion of the nozzle portion is located adjacent to a surface of the substrate 1.

A second end portion of each of the nozzle pipes 11a, 11b and 11c, which is opposite to the first end portion, is vertically bent and is connected to a connection member 16a, 16b or 16c that is connected to one of the solution reservoirs, respectively.

Each of the connection units 16a, 16b and 16c extends downwards and thus flow paths along which the processing solutions flow is provided from the solution reservoirs 15 to each of the nozzle pipes 11a, 11b and 11c in each of the connection units 16a, 16b and 16c. The connection units 16a, 16b and 16c are arranged in a cylindrical housing 17 adjacent to the bowl 3 of the facility. However, the above conventional apparatus for supplying the processing solutions has a relatively complex structure, and thus an operation unit for operating and controlling each unit of the apparatus may have a necessarily complex structure. Further, elevation and rotation of the nozzle pipes may be performed through complicated processing sequences and moving paths of the units may become longer, to thereby remarkably increase time and cost in supplying the processing solutions onto the substrate. In addition, costs for manufacturing the conventional apparatus may be high due to the complex structure thereof.

In a modification of the conventional apparatus for supplying the processing solutions, various nozzle pipes, through which different kinds of the processing solutions respectively flow, and a single nozzle that is connected to the nozzle pipes are arranged in a single housing. In such a modified apparatus, a previous processing solution may remain in the nozzle when a subsequent processing solution is injected through the nozzle, because the previous processing solution and the subsequent processing solution are injected through the same nozzle. In addition, when an etching solution, such as that containing an aqueous hydrogen fluoride (HF) solution is supplied onto the substrate, there is a problem in that the nozzle may be contaminated by fumes of the etching solution.

### SUMMARY OF THE INVENTION

An example embodiment of the present invention provides a nozzle assembly having a simple structure.

Another example embodiment of the present invention provides an apparatus for supplying various processing solutions onto a substrate while reducing contamination of a nozzle due to different kinds of the processing solutions.

Still another example embodiment of the present invention provides a method of supplying various processing solutions onto a substrate while reducing contamination due to the processing solutions in different nozzles using the above apparatus.

According to some example embodiments of the present invention, there is provided a nozzle assembly including a housing, a plurality of supply lines arranged in the housing, different processing solutions flowing onto a substrate through each of the supply lines and a plurality of nozzles connected to the supply lines, respectively, in such a configuration that a first nozzle selected from the nozzles is directed to the substrate and the remaining nozzles excluding the first nozzle are directed away from the substrate. For example, the nozzles are connected to the supply lines at an end portion of the housing in such a trigonal pyramid structure that the end portion of the housing is located at the apex of the pyramid and the nozzles are located at corners of a trigonal base. The housing includes a stationary part extending in a first direction and a rotating part movably secured to the stationary part in a second direction perpendicular to the first direction and parallel with a surface of the substrate, and the nozzles are arranged on a circular coplanar surface of which a normal vector is parallel with the second direction and spaced apart from one another by substantially the same angular distance. The nozzles are arranged on the circular coplanar surface in the trigonal pyramid structure and are spaced apart from one another by substantially the same central angle of about 120°. The nozzle assembly further includes a driving unit for driving the housing and the driving unit includes a motor for generating rotational power and a controller for controlling the motor in such a manner that the nozzles connected to the supply lines rotate less than an angular distance of about 180° clockwise or counterclockwise.

According to some example embodiments of the present invention, there is provided an apparatus for supplying processing solutions onto a substrate including a rotating chuck supporting a substrate, a solution reservoir in which various processing solutions are stored, a nozzle assembly including a plurality of supply lines adjacent to the rotating chuck and through which the processing solutions flow from the solution reservoir to the substrate, a housing in which the supply lines are arranged and a plurality of nozzles connected to the supply lines, respectively, in such a configuration that a first nozzle selected from the nozzles is directed to the substrate and the remaining nozzles excluding the first nozzle are directed away from the substrate and a driving member driving the housing, so that the supply lines in the housing are rotated. The housing includes a stationary part stationarily secured to a bottom portion of the apparatus and extending in a first direction perpendicular to a surface of the rotating chuck, and a rotating part movably secured to an end portion of the stationary part and extending from the end portion of the stationary part in a second direction perpendicular to the first direction and parallel with the surface of the rotating chuck. The rotating part rotates with respect to a central axis thereof. The nozzles are connected to the supply lines at an end portion of the rotating part of the housing in such a trigonal pyramid structure that the end portion of the rotating part is located at the apex of the pyramid and the nozzles are located at corners of a trigonal base. The nozzles are arranged on a circular coplanar surface of which a normal vector is parallel with the second direction and spaced apart from one another by substantially the same angular distance. The driving member includes a motor for applying rotational power to the housing in which the supply lines are arranged and a controller for controlling the motor in such a manner that the nozzles connected to the supply lines rotate less than an angular distance of about 180° clockwise or counterclockwise.

According to some example embodiments of the present invention, there is provided a method of supplying processing solutions onto a substrate using a nozzle assembly including a housing, a plurality of supply lines arranged in the housing and through which different processing solutions flow onto the substrate, and a plurality of nozzles connected to the supply lines, respectively, in such a configuration that a first nozzle selected from the nozzles is directed to the substrate and the remaining nozzles excluding the first nozzle are directed away from the substrate. A first supply line is determined among the supply lines through which a first processing solution flows. The first supply line is connected to a first nozzle. The first supply line is selected merely by rotation of the housing with respect to an axis thereof parallel with a surface of the substrate in such a manner that the first nozzle connected to the first supply line is directed to the substrate. The first processing solution may be supplied onto the substrate through the first nozzle. The remaining processing solutions excluding first processing solution remain in the remaining supply lines that are connected to the remaining nozzles excluding the first nozzle, respectively, and the remaining nozzles are directed away from the substrate while the first processing solution is supplied onto the substrate through the first nozzle. At least three nozzles are connected to the supply lines at an end portion of the housing in such a trigonal pyramid structure that the end portion of the housing is located at the apex of the pyramid and the nozzles are located at corners of a trigonal base, and the nozzles are arranged on a circular coplanar surface of which a normal vector is directed parallel with a surface of the substrate and spaced apart from one another by substantially the same angular distance.

According to some example embodiments of the present invention, processing solutions may be independently and individually supplied onto a substrate and thus a non-operational nozzle may be prevented from being contaminated by the supply of the processing solution through an operational nozzle. Accordingly, when the non-operational nozzle is changed into a new operational nozzle, the processing solutions may be supplied onto the substrate without any contaminants. Further, selection among the nozzles merely by the rotation of the housing may simplify the structure of the supply apparatus. For those reasons, the supply apparatus in the present example embodiments may be utilized in a manufacturing process for a flat panel display device as well as a semiconductor manufacturing process.

### BRIEF DESCRIPTION OF THE DRAWINGS

Example embodiments will be more clearly understood from the following detailed description taken in conjunction with the accompanying drawings. FIGS. 1 to 4 represent non-limiting, example embodiments as described herein.

FIG. 1 is a view illustrating a schematic structure of a conventional apparatus for supplying processing solutions onto a substrate;

FIG. 2 is a cross-sectional view illustrating a nozzle assembly in accordance with an example embodiment of the present invention;

FIG. 3 is a right side view of the nozzle assembly shown in FIG. 2;

FIG. 4 is a cross-sectional view taken along a line I-I′ of FIG. 2;

FIG. 5 is a cross-sectional view illustrating an apparatus for supplying processing solutions onto a substrate in accordance with an example embodiment of the present invention; and

FIG. 6 is a flowchart showing processing steps for a method of supplying processing solutions onto a substrate using the apparatus shown in FIG. 5.

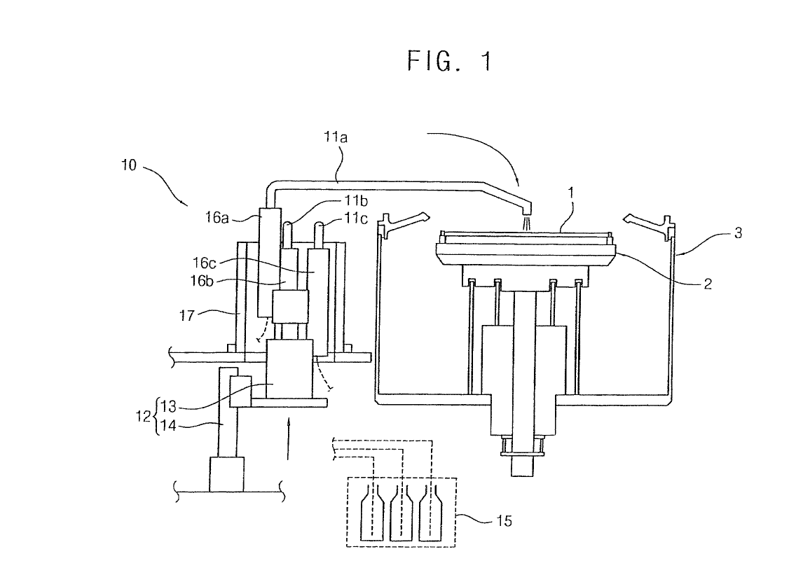

### DETAILED DESCRIPTION OF THE INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

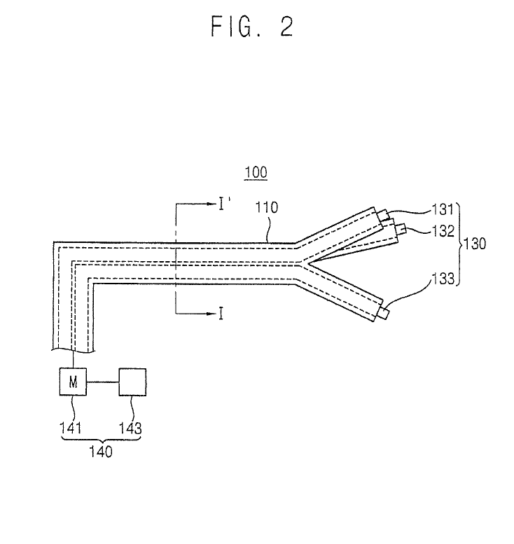

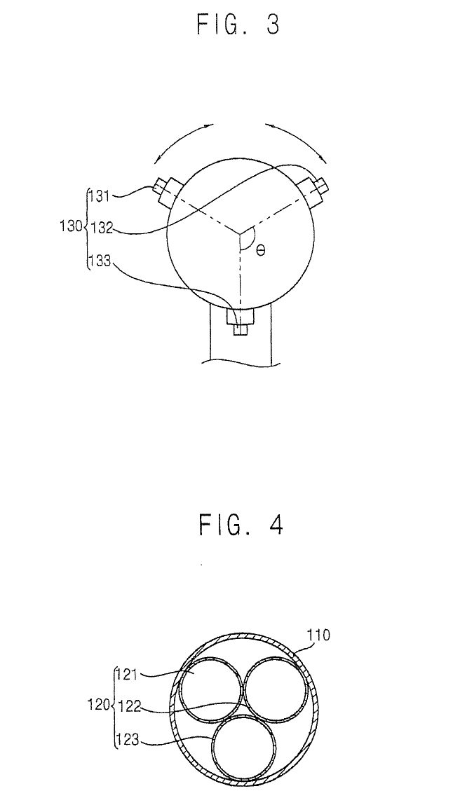

FIG. 2 is a cross-sectional view illustrating a nozzle assembly in accordance with an example embodiment of the present invention. FIG. 3 is a right side view of the nozzle assembly shown in FIG. 2. FIG. 4 is a cross-sectional view taken along a line I-I′ of FIG. 2.

Referring to FIGS. 2 to 4, the nozzle assembly 100 in accordance with an example embodiment of the present invention may include a housing 110, a plurality of supply lines 120 arranged in the housing 110 and a plurality of nozzles 130 connected to the supply lines 120, respectively. Processing solutions may flow through each of the supply lines 120 and may be supplied onto a substrate through each of the nozzles 130. The nozzle assembly 100 may be used for processing a semiconductor substrate or a glass substrate for a flat panel of a flat panel display device.

In an example embodiment, the housing 110 may be shaped into a cylinder and may be rotated with respect to a central axis of the cylinder. The cylindrical housing 110 may be vertically bent and extend in a direction parallel with a surface of the substrate. In the present example embodiment, the housing 110 is shaped into a hollow cylinder, so that a plurality of the supply lines 120 is arranged in an internal space of the cylinder.

The supply lines 120 may be positioned in the internal space of the cylindrical housing 110. In an example embodiment, the supply lines 120 may be separated from one another in the housing 110, so that each of the supply lines 120 may provide an individual flow path through which the processing solutions independently flow. The supply lines 120 may be mechanically separated from the housing 110. Otherwise, the supply lines 120 may be secured to the housing 110, so that the supply lines 120 may be rotated together with the housing 110.

The processing solutions flowing in each of the supply lines 120 may be different from one another. In the present example embodiment, three supply lines 121, 122 and 123 are provided in the housing 110. However, the number of the supply lines 120 may be varied in accordance with process conditions and environments.

In an example embodiment, the nozzles 130 may be connected to the supply lines 120, respectively. The nozzles 130 may also be shaped into a cylinder. The nozzles 130 may be connected to the supply lines 120, respectively, at a first end portion of the housing 110 in such a configuration that the nozzles 130 are arranged on a coplanar surface of which the normal vector is parallel with the extension direction of the housing 110 and spaced apart from one another by substantially the same distance. In the present example embodiment, since three supply lines 120 are provided in the housing 110, three nozzles 130 are connected to the supply lines 120, respectively, and are arranged on a circular coplanar surface at substantially the same central angle (θ) of about 120°. That is, the first end portion of the housing 110 and the three nozzles 130 may form a trigonal pyramid in which the first end portion of the housing is positioned at the apex of the pyramid and the nozzles 130 are positioned at the corners of a trigonal base.

When one of the nozzles 130 is selected and operated for supplying the processing solutions downward onto the substrate, an operational nozzle 133 may be located at an injection position P1 at which the operational nozzle 133 is directed downwards to the substrate and the other unselected nozzles 131 and 132 may remain non-operational and be located at a holding position P2 at which the non-operational nozzles 131 and 132 are directed upwards away from the substrate. Therefore, a processing solution may be injected onto the substrate through the operational nozzle 133 located at the injection position P1 and may be stored without injection in the non-operational nozzles 131 and 132 located at the holding position P2. Accordingly, the non-operational nozzles 131 and 132 may be prevented from being contaminated by fumes generated when the processing solution is injected onto the substrate from the operational nozzle 133. The selection of the nozzles 130 may be performed by rotation of the cylindrical housing 110 with respect to the central axis thereof. That is, when the cylindrical housing 110 may be rotated to an angular distance corresponding to an angle of about 120°, one of the unselected nozzles 131 and 132 may be selected as a new operational nozzle, and thus the processing solution in the supply line connected to the new operational nozzle may be injected onto the substrate. That is, the selection of the operational nozzle may be performed merely by rotation of the housing 110. Therefore, selection of the operational nozzle from the nozzles 130 may be much simpler and easier, and the simple selection process of the operation nozzle may simplify the structure of the nozzle assembly 100.

In an example embodiment, the nozzles 130 may be secured to the housing 110 and thus the nozzles 130 may be rotated together with the housing 110.

A second end portion of the housing 110, which may be opposite to the first end portion in a longitudinal direction of the housing 110, may include an opening through which a driving unit 140 may be connected to the housing 110.

In an example embodiment, the driving unit 140 may include a motor 141 rotating the housing 110 to which the supply lines 130 are secured and a controller 143 for controlling the rotation speed and a rotation angle of the motor 141. Accordingly, the rotation speed, a rotation angle and a supplying time of each of the supply lines 130 may be determined by the controller 143 because the supply lines 130 are rotated together with the housing 110.

In an example embodiment, the housing 110 may be rotated less than an angular distance of 180° clockwise or counterclockwise from a stationary position of the supply lines 120. For example, in case that first, second and third supply lines 120 are arranged in the housing 110 in a clockwise sequence and spaced apart from one another by substantially the same angular distance of about 120° and the second nozzle connected to the second supply line is selected as the operational nozzle and the first and third nozzles connected to the first and third supply lines are selected as the non-operational nozzles, the housing 110 may be rotated at an angular distance of about 120° clockwise rather than be rotated at an angular distance of about 240° counterclockwise from the stationary position of the second supply line when the operational nozzle is to be changed to the third nozzle from the second nozzle. That is, the change of the operational nozzle is performed by rotation of the housing 110 of which the angular distance is less than about 180°. Accordingly, the nozzles 130 respectively connected to the supply lines 130 are directed towards the substrate by the rotation of the housing 110 of which the central angle is less than about 180° with a less twist of the supply lines in the housing 110, and thus the processing solutions are injected onto the substrate independently from one another while minimizing twisting of the supply lines 120. Accordingly, the nozzle assembly 100 may be sufficiently prevented from being damaged by the twisting of the supply lines 120 in the housing 110.

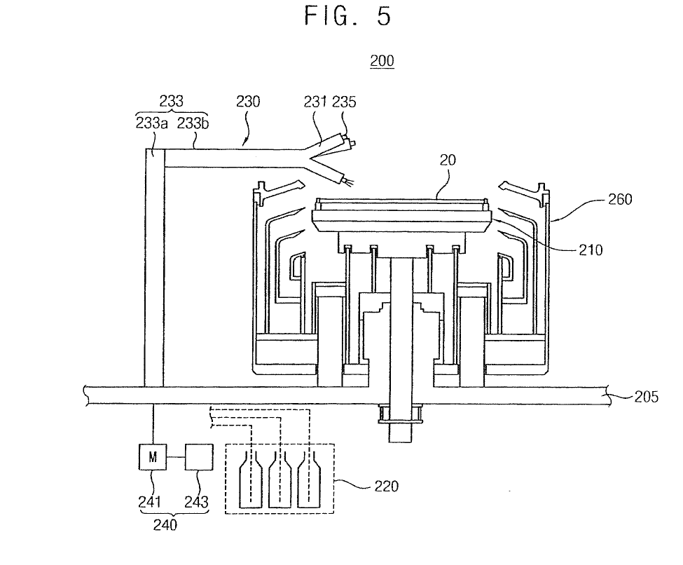

FIG. 5 is a cross-sectional view illustrating an apparatus for supplying processing solutions onto a substrate in accordance with an example embodiment of the present invention.

Referring to FIG. 5, the apparatus 200 for supplying processing solutions onto a substrate (hereinafter referred to as supply apparatus) may include a rotating chuck 210 on which the substrate 20 is positioned and a bowl 260 surrounding the chuck 210 including the substrate 20. Although not illustrated in detail, the chuck 210 and the bowl 260 may be arranged in a process chamber (not shown). In the present example embodiment, the chuck 210 and the bowl 260 may be positioned on a base plate 205.

A plurality of storage spaces isolated by separation walls may be provided in the bowl 260 and the residual processing solutions may be stored into the storage spaces after completing the process on the substrate using the processing solutions. A plurality of drain pipes (not shown) may be connected to the storage spaces, respectively, so that the residual processing solutions may be discharged from the bowl 260 in accordance with the kinds of the processing solutions. In addition, the supply apparatus 200 may further include a recycling unit (not shown) for recycling the residual processing solutions. The supply apparatus 200 may further include a pump system (not shown) for removing minute particles from the bowl while performing the process on the substrate using the processing solutions.

The supply apparatus 200 may further include a solution reservoir 220 storing various processing solutions, a nozzle assembly 230 for supplying the processing solutions onto the substrate 20 from the solution reservoir 220 and a driving member 240 for driving the nozzle assembly 230.

The solution reservoir 220 may store the processing solutions therein. Examples of the processing solutions may include an aqueous hydrogen fluoride (HF) solution, a standard cleaning 1 (SC-1) solution and deionized pure water. The processing solutions may be determined in accordance with process conditions and environments such as impurities that are to be removed from the bowl 260 and a thin layer that is to be coated on the substrate. For example, the solution reservoir 220 may include a solution tank (not shown) for storing the processing solutions and a plurality of feeding lines (not shown) for feeding the processing solutions to the nozzle assembly, respectively. The solution tank may be rotated at a constant angular speed or may be maintained at a constant temperature while processing the substrate in the process chamber.

In an example embodiment, the nozzle assembly 230 may include a plurality of supply pipes 231, a housing 233 and a plurality of nozzles 235.

The supply pipes 231 may be connected to the solution reservoir 220 and each of the supply pipes 231 may include flow paths through which the processing solutions flow from the solution reservoir 220 to the substrate 20.

The housing 233 may hold the supply pipes 231 therein. In the present example embodiment, the housing 233 may include a stationary part 233a protruded upwards from the base plate 205 perpendicularly to a surface of the chuck 210 and a rotating part 233b extended from the stationary part 233a in a direction parallel with the surface of the chuck 210. The stationary part 233a and the rotating part 233b may be shaped into a hollow cylinder, so that the supply pipes 231 may be arranged in an internal space of the hollow cylindrical housing 233.

The stationary part 233a may be stationarily secured to the base plate 205 and the rotating part 233b may be movably secured to an end portion of the stationary part 233a. The rotating part 233b may be rotated with respect to a central axis thereof, so that the nozzles connected to an end portion of the rotating part 233b may be positioned adjacent to the substrate.

In an example embodiment, the supply pipes 231 may be positioned in the internal space of the cylindrical housing 233. The supply pipes 231 may be separated from one another in the housing 110, so that each of the supply pipes 231 may provide an individual flow path through which the processing solutions independently flow. The supply pipes 231 may be mechanically separated from the housing 233. Otherwise, the supply pipes 231 may be secured to the housing 233, so that the supply pipes 231 may be rotated together with the housing 233.

The processing solutions may flow individually and independently through the supply pipes 231, and thus the processing solutions flowing in each of the supply pipes 231 may be different from one another. In the present example embodiment, three supply pipes 231 are provided in the housing 233. However, the number of the supply pipes 231 may be varied in accordance with process conditions and environments.

In an example embodiment, the nozzles 235 may be connected to the supply pipes 231, respectively. The nozzles 235 may also be shaped into a cylinder. The nozzles 235 may be connected to the supply pipes 231, respectively, at the end portion of the rotating part 233b of the housing 233 in such a configuration that the nozzles 235 are arranged on a coplanar surface of which the normal vector is parallel with the central axis of the rotating part 233b of the housing 233 and spaced apart from one another by substantially the same distance. In the present example embodiment, since three supply pipes 231 are provided in the housing 233, three nozzles 235 are connected to the supply pipes 231, respectively, and are arranged on a circular coplanar surface at substantially the same central angle (θ) of about 120°. That is, the first end portion of the housing 233 and the three nozzles 235 may form a trigonal pyramid in which the first end portion of the housing 233 is positioned at the apex of the pyramid and the nozzles 235 are positioned at the corners of a trigonal base.

When one of the nozzles 235 is selected and operated for supplying the processing solutions downward onto the substrate, a selected nozzle (operational nozzle) may be located at an injection position at which the operational nozzle is directed downwards to the substrate and the other unselected nozzles (non-operational nozzles) may remain non-operational and be located at a holding position at which the non-operational nozzles are directed upwards away from the substrate. Accordingly, the non-operational nozzles may be prevented from being contaminated by fumes generated when a processing solution is injected onto the substrate from the operational nozzle.

The selection of the nozzles 235 may be performed by rotation of the cylindrical rotating part 233b with respect to the central axis thereof. That is, when the cylindrical rotating part 233b may be rotated to an angular distance corresponding to an angle of about 120°, one of the unselected nozzles may be selected as a new operational nozzle, and thus the processing solution in the supply pipe connected to the new operational nozzle may be injected onto the substrate. That is, the selection of the operational nozzle may be performed merely by rotation of the housing 233. Therefore, selection of the operational nozzle from the nozzles 235 may be much simpler and easier, and the simple selection process of the operation nozzle may simplify the structure of the nozzle assembly 200.

In an example embodiment, the nozzles 235 may be secured to the housing 233 and thus the nozzles 235 may be rotated together with the housing 233. Accordingly, the operational nozzle and the supply pipe connected to the operational nozzle may be directed toward the substrate 20 and the non-operational nozzle and the supply pipes connected to the non-operational nozzle may be directed away from the substrate 20.

An end portion of the stationary part 233a of the housing 233 may include an opening through which a driving member 240 may be connected to the housing 233.

In an example embodiment, the driving member 240 may include a motor 241 for rotating the housing 233 to which the supply pipes 231 are secured and a controller 243 for controlling the rotation speed and a rotation angle of the motor 241. Accordingly, the rotation speed, a rotation angle and a supplying time of each of the supply pipes 231 may be determined by the controller 243 because the supply pipes 231 are rotated together with the housing 230.

In an example embodiment, the housing 233 may be rotated less than an angular distance of 180° clockwise or counterclockwise from a stationary position of the supply pipes 231. For example, when three supply pipes 231 are arranged in the housing 235, the housing 235 may be rotated at an angular distance of about 120° clockwise or counterclockwise from the stationary position of the supply pipe connected to the operational nozzle. Accordingly, the nozzles 235 respectively connected to the supply pipes 231 are sequentially directed towards the substrate 20, and thus the processing solutions are sequentially injected onto the substrate 20 independently from one another. In addition, since the supply pipes 231 may be rotated together with the housing 233, the supply pipes 231 may be prevented from being twisted with one another, to thereby prevent damage to the supply pipes 231 due to the twisting thereof.

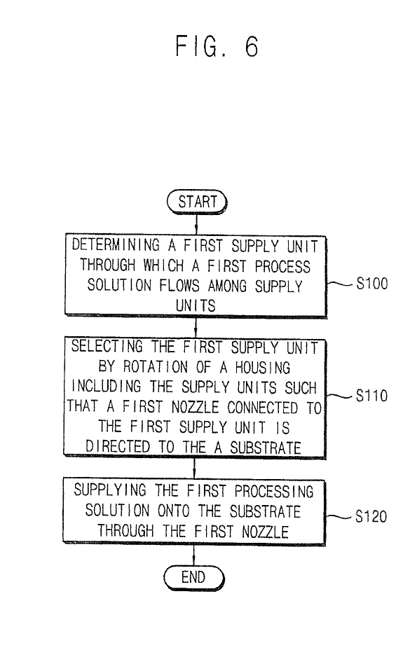

FIG. 6 is a flowchart showing processing steps for a method of supplying processing solutions onto a substrate using the apparatus shown in FIG. 5.

Referring to FIGS. 5 and 6, a first processing solution for a given process may be determined in view of process conditions and environments, and a first supply pipe through which the first processing solution flows may be determined based on supply pipe information (step S100). Then, the first supply pipe may be selected among the supply pipes 231 by rotation of the housing 233 (step S110). For example, the rotating part 233b of the housing 233 may be rotated with respect to a central axis thereof, and thus the nozzle connected to the first supply pipe may be directed to the substrate 20 and the remaining nozzles connected to the remaining supply pipes excluding the first supply pipe may be directed away from the substrate 20. That is, the operational nozzle through which the first processing solution may be injected onto the substrate may be located at the injection position and the non-operational nozzle through which the remaining processing solutions excluding the first processing solution are injected may be located at the holding position.

Then, the first processing solution may be injected onto the substrate 20 through the operational nozzle (step S120). The processing solutions may include an aqueous hydrogen fluoride (HF) solution, a standard cleaning 1 (SC-1) solution and deionized pure water. The processing solutions may be determined in accordance with process conditions and environments such as impurities that are to be removed from the bowl 260 and a thin layer that is to be coated on the substrate. When the first processing solution is sufficiently supplied onto the substrate 20, a second supply pipe through which a second processing solution flows may be selected by substantially the same rotation of the housing 233 in such a manner that the nozzle connected to the second supply pipe is located at the injection position as the operational nozzle and the remaining nozzles excluding the second nozzle is located at the holding position as the non-operational nozzles. The above selection of the operation nozzle and the non-operational nozzles by the rotation of the housing 233 may be repeated until the process on the substrate 20 is completed in the process chamber. While performing the supply of the processing solutions onto the substrate 20, the substrate 20 may maintain a rotation at a given rotation speed in the bowl 260.

According to some example embodiments of the present invention, processing solutions may be independently and individually supplied onto a substrate and thus a non-operational nozzle may be prevented from being contaminated by the supply of a processing solution through an operational nozzle. Accordingly, when the non-operational nozzle is changed into a new operational nozzle, the processing solution may be supplied onto the substrate without any contaminants. Further, the selection of the nozzles by rotation of a housing may simplify the structure of a supply apparatus. For those reasons, the supply apparatus in the present example embodiments may be utilized in a manufacturing process for a flat panel display device as well as a semiconductor manufacturing process.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included less than the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A nozzle assembly comprising:
a housing;
a plurality of supply units arranged in the housing, different processing solutions flowing onto a substrate through each of the supply units; and
a plurality of nozzles connected to the supply units, respectively, in such a configuration that a first nozzle selected from the nozzles is directed to the substrate and the remaining nozzles excluding the first nozzle are directed away from the substrate.

2. The nozzle assembly of claim 1, wherein the nozzles are connected to the supply units at an end portion of the housing in such a trigonal pyramid structure that the end portion of the housing is located at an apex of the pyramid and the nozzles are located at corners of a trigonal base.

3. The nozzle assembly of claim 2, wherein the housing includes a stationary part extending in a first direction and a rotating part movably secured to the stationary part in a second direction perpendicular to the first direction and parallel with a surface of the substrate, and the nozzles are arranged on a circular coplanar surface of which a normal vector is parallel with the second direction and spaced apart from one another by substantially the same angular distance.

4. The nozzle assembly of claim 3, wherein three nozzles are arranged on the circular coplanar surface in the trigonal pyramid structure and are spaced apart from one another by substantially the same central angle of about 120°.

5. The nozzle assembly of claim 1, further comprising a driving unit for driving the housing, the driving unit including a motor for generating rotational power and a controller for controlling the motor in such a manner that the nozzles connected to the supply units rotate less than an angular distance of about 180° clockwise or counterclockwise.

6. An apparatus for supplying processing solutions onto a substrate, comprising:
a rotating chuck supporting a substrate;
a solution reservoir in which various processing solutions are stored;
a nozzle assembly including a plurality of supply units adjacent to the rotating chuck and through which the processing solutions flow from the solution reservoir to the substrate, a housing in which the supply units are arranged and a plurality of nozzles connected to the supply units, respectively, in such a configuration that a first nozzle selected from the nozzles is directed to the substrate and the remaining nozzles excluding the first nozzle are directed away from the substrate; and
a driving member for rotating the housing and the supply units in the housing.

7. The apparatus of claim 6, wherein the housing includes:
a stationary part stationarily secured to a bottom portion of the apparatus and extending in a first direction perpendicular to a surface of the rotating chuck; and
a rotating part movably secured to an end portion of the stationary part and extending from the end portion of the stationary part in a second direction perpendicular to the first direction and parallel with the surface of the rotating chuck, the rotating part rotating with respect to a central axis thereof.

8. The apparatus of claim 7, wherein the nozzles are connected to the supply units at an end portion of the rotating part of the housing in such a trigonal pyramid structure that the end portion of the rotating part is located at an apex of the pyramid and the nozzles are located at corners of a trigonal base.

9. The apparatus of claim 8, wherein the nozzles are arranged on a circular coplanar surface of which a normal vector is parallel with the second direction and spaced apart from one another by substantially the same angular distance.

10. The apparatus of claim 6, wherein the driving member includes a motor for applying rotational power to the housing in which the supply units are arranged and a controller for controlling the motor in such a manner that the nozzles connected to the supply units rotate less than an angular distance of about 180° clockwise or counterclockwise.

11. A method of supplying processing solutions onto a substrate using a nozzle assembly including a housing, a plurality of supply units arranged in the housing and through which different processing solutions flow onto the substrate, and a plurality of nozzles connected to the supply units, respectively, in such a configuration that a first nozzle selected from the nozzles is directed to the substrate and the remaining nozzles excluding the first nozzle are directed away from the substrate, comprising:
determining a first supply line among the supply units through which a first processing solution flows and connected to a first nozzle; and
selecting the first supply line by rotation of the housing with respect to an axis thereof parallel with a surface of the substrate in such a manner that the first nozzle connected to the first supply line is directed to the substrate; and
supplying the first processing solution onto the substrate through the first nozzle.

12. The method of claim 11, wherein the remaining processing solutions excluding the first processing solution remain in the remaining supply units that are connected to the remaining nozzles excluding the first nozzle, respectively, and the remaining nozzles are directed away from the substrate while the first processing solution is supplied onto the substrate through the first nozzle.

13. The method of claim 11, wherein at least three nozzles are connected to the supply units at an end portion of the housing in such a trigonal pyramid structure that the end portion of the housing is located at an apex of the pyramid and the nozzles are located at corners of a trigonal base, and the nozzles are arranged on a circular coplanar surface of which a normal vector is directed parallel with a surface of the substrate and spaced apart from one another by substantially the same angular distance.
